(19) United States
(12) Patent Application Publication
(10) Pub. No.: US 2026/0187783 A1
(43) Pub. Date: Jul. 2, 2026

(54) ALGORITHM PERFORMANCE PREDICTION FOR EXAMINATION OF SEMICONDUCTOR SPECIMENS

(71) Applicant: Applied Materials Israel Ltd., Rehovot (IL)

(72) Inventor: Lior AKERMAN, Mazkeret-Batya (IL)

(21) Appl. No.: 19/004,150

(22) Filed: Dec. 27, 2024

(51) Int. Cl. G06T 7/00; G06T 7/11; G06T 7/174; G06T 7/60

(52) U.S. Cl. CPC G06T 7/001; G06T 7/11; G06T 7/174; G06T 7/60; G06T 2207/30148

(57) ABSTRACT

There is provided a system and method of algorithm performance prediction. The method includes obtaining one or more sets of images acquired from one or more sites of a semiconductor specimen to be examined by a target algorithm; extracting values of a set of image attributes from the one or more sets of images, wherein the set of image attributes is expected to result in varied responses from the target algorithm; and providing the values of the set of image attributes to a variation model to predict performance of the target algorithm with respect to a performance metric without executing the target algorithm on the sets of images, wherein the variation model is constructed to predict how the target algorithm responds to variations in values of the set of image attributes.

### TECHNICAL FIELD

The presently disclosed subject matter relates, in general, to the field of examination of a semiconductor specimen, and more specifically, to performance evaluation of an algorithm usable for examining a specimen.

### BACKGROUND

Current demands for high density and performance associated with ultra large-scale integration of fabricated devices require submicron features, increased transistor and circuit speeds, and improved reliability. As semiconductor processes progress, pattern dimensions such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

Examination can be provided by using non-destructive examination tools during or after manufacture of the specimen to be examined. A variety of non-destructive examination tools includes, by way of non-limiting example, scanning electron microscopes, atomic force microscopes, optical inspection tools, etc.

Examination processes can include a plurality of examination steps. The manufacturing process of a semiconductor device can include various procedures such as etching, depositing, planarization, growth such as epitaxial growth, implantation, etc. The examination steps can be performed a multiplicity of times, for example after certain process procedures, and/or after the manufacturing of certain layers, or the like. Additionally, or alternatively, each examination step can be repeated multiple times, for example for different wafer locations, or for the same wafer locations with different examination settings.

Examination processes are used at various steps during semiconductor fabrication for various examination applications, such as, for example, defect detection, Automatic Defect Classification (ADC), Automatic Defect Review (ADR), image segmentation, and automated metrology-related operations, etc.

The various examination applications, such as metrology and defect examination, typically rely on specialized examination algorithms, often referred to as “recipes.” In this context, algorithms or recipes are computational processes designed to analyze acquired specimen data, such as images, to extract critical information relevant to the examination objective of the applications. By way of example, for metrology applications, common algorithms include critical dimension (CD) algorithms, which measure the dimensions of fine features on the wafer, and overlay algorithms, which assess the alignment or misalignment between layers of the semiconductor device. For defect examination, algorithms are utilized to identify potential defects, classify their types, and review inspection results. These algorithms are integral to optimizing the examination processes, enabling precise, efficient, and repeatable monitoring of semiconductor manufacturing.

### SUMMARY

In accordance with certain aspects of the presently disclosed subject matter, there is provided a computerized system of algorithm performance prediction, the system comprising a processing circuitry configured to obtain one or more sets of images acquired from one or more sites of a semiconductor specimen to be examined by a target algorithm; extract values of a set of image attributes from the one or more sets of images, wherein the set of image attributes is expected to result in varied responses from the target algorithm; and provide the values of the set of image attributes to a variation model to predict performance of the target algorithm with respect to a performance metric without executing the target algorithm on the sets of images, wherein the variation model is constructed to predict how the target algorithm responds to variations in values of the set of image attributes.

In addition to the above features, the system according to this aspect of the presently disclosed subject matter can comprise one or more of features (i) to (x) listed below, in any desired combination or permutation which is technically possible:
(i). The set of image attributes can comprise a subset of value attributes and a subset of statistical attributes derived from the one or more sets of images.
(ii). The target algorithm can be a metrology algorithm and the performance metric can be precision indicative of repeatability of metrology measurements obtained from the semiconductor specimen.
(iii). The variation model can be constructed to predict a relationship between output variations of the target algorithm and the subset of statistical attributes, the relationship being parameterized by a position within a multi-dimensional attribute space defined by values of the subset of value attributes.
(iv). The target algorithm can be an overlay algorithm usable for obtaining an overlay measurement between a first layer and a second layer in the semiconductor specimen. Each set of images acquired from a respective site can comprise at least one image for each layer, and the set of image attributes can comprise a pair of gray level (GL) profiles corresponding to a pair of regions of interest (ROIs) defined on each layer, and noise statistics extracted from the pair of ROIs.
(v). The overlay algorithm can be configured based on a correlation graph between the pair of GL profiles for each layer. The variation model can be configured to predict a probability of correlation noises surpassing a correlation maximum indicated by the correlation graph.
(vi). The probability of the correlation noises surpassing the correlation maximum can be calculated based on the correlation noise and a gap between a correlation value at each position of the correlation graph and the correlation maximum.
(vii). The predicted performance can be with respect to precision of the overlay measurement, which is determined based on predictions derived independently from a secondary electron (SE) image and a backscattered electron (BSE) image.
(viii). The variation model can be further configured to estimate a statistical error representing variations in overlay measurements based on probabilities calculated across a range of delta distances from the correlation maximum.
(ix). The target algorithm can be a critical dimension (CD) algorithm usable for providing a CD measurement for a given feature of the semiconductor specimen, and the performance metric can be precision.
(x). The target algorithm can be a defect examination algorithm usable for examining the semiconductor specimen, and the performance metric can be detection accuracy of defects detected in the semiconductor specimen.

In accordance with other aspects of the presently disclosed subject matter, there is provided a computerized method of algorithm performance prediction, the method comprising: obtaining one or more sets of images acquired from one or more sites of a semiconductor specimen to be examined by a target algorithm; extracting values of a set of image attributes from the one or more sets of images, wherein the set of image attributes is expected to result in varied responses from the target algorithm; and providing the values of the set of image attributes to a variation model to predict performance of the target algorithm with respect to a performance metric without executing the target algorithm on the sets of images, wherein the variation model is constructed to predict how the target algorithm responds to variations in values of the set of image attributes.

These aspects of the disclosed subject matter can comprise one or more of features (i) to (x) listed above with respect to the system, mutatis mutandis, in any desired combination or permutation which is technically possible.

In accordance with other aspects of the presently disclosed subject matter, there is provided a non-transitory computer readable medium comprising instructions that, when executed by a computer, cause the computer to perform a method of algorithm performance prediction, the method comprising: obtaining one or more sets of images acquired from one or more sites of a semiconductor specimen to be examined by a target algorithm; extracting values of a set of image attributes from the one or more sets of images, wherein the set of image attributes is expected to result in varied responses from the target algorithm; and providing the values of the set of image attributes to a variation model to predict performance of the target algorithm with respect to a performance metric without executing the target algorithm on the sets of images, wherein the variation model is constructed to predict how the target algorithm responds to variations in values of the set of image attributes.

This aspect of the disclosed subject matter can comprise one or more of features (i) to (x) listed above with respect to the system, mutatis mutandis, in any desired combination or permutation which is technically possible.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a generalized flowchart of algorithm performance prediction in accordance with certain embodiments of the presently disclosed subject matter.

FIG. 3 illustrates a generalized flowchart of setup phase procedures in accordance with certain embodiments of the presently disclosed subject matter.

FIG. 4 illustrates an example of a pair of images acquired for two layers in accordance with certain embodiments of the presently disclosed subject matter.

FIG. 5 provides a schematic illustration of the COS (Center of Symmetry) identification process in accordance with certain embodiments of the presently disclosed subject matter.

FIG. 6 shows a schematic illustration of calculating the probability of noises surpassing the correlation maximum of a correlation graph in accordance with certain embodiments of the presently disclosed subject matter.

FIG. 7 illustrates a schematic block diagram of the performance prediction process for an overlay algorithm in accordance with certain embodiments of the presently disclosed subject matter.

FIG. 8 shows a comparison between the prediction results obtained using the proposed process and the actual measurements derived from executing the overlay algorithm on the image datasets in accordance with certain embodiments of the presently disclosed subject matter.

### DETAILED DESCRIPTION OF EMBODIMENTS

The process of semiconductor manufacturing often requires multiple sequential processing steps and/or layers, some of which could possibly cause errors that may lead to yield loss. Various examination applications, such as defect-related applications (e.g., defect detection, defect review, and defect classification, etc.), and/or metrology-related applications (e.g., critical dimension (CD) measurements, etc.), can be performed at different processing steps/layers during the manufacturing process to monitor and control the process.

These examination applications typically involve the use of complex algorithms, such as metrology algorithms, which are designed for metrology applications, such as, e.g., measuring CD or overlay, and defect detection algorithms, which are designed for defect applications, such as identifying and classifying defects on the semiconductor specimen. To evaluate and optimize the performance of these algorithms with respect to specific performance metrics, it is traditionally necessary to acquire a significant number of images from multiple sites on a wafer. This not only requires substantial tool time, but also limits the ability to test a wide range of imaging configurations for optimization purposes, such as wafer throughput, imaging duration, and computational resources. As a result, the ability to optimize recipes within the allocated tool time is significantly constrained, potentially impacting the accuracy and reliability of the semiconductor manufacturing process.

Byway of example, one prominent type of metrology algorithm is the overlay algorithm, which is used to measure the misalignment (commonly referred to as offset or shift) between two layers of a semiconductor specimen. During semiconductor fabrication, multiple layers are sequentially processed and aligned to ensure proper functionality of the final device. An overlay algorithm analyzes images acquired from features on these layers to calculate the offset values, typically in nanometers, between relevant features in one layer and relevant features in the other. This information is crucial for determining whether the layers are properly aligned, or if corrective action is necessary.

A key performance metric for metrology algorithms, including overlay algorithms, is precision. Precision refers to the closeness of agreement between independent measurements on the same feature of a specimen. High precision indicates that the independent measurements of the same feature are repeatable, meaning the measurements exhibit small variance and the distribution of results is relatively tight. Precision can be regarded as the repeatability of independent measurements. In some embodiments, it comprises two components: repeatability and reproducibility.

Repeatability refers to the consistency of measurement results when consecutive measurements are conducted repeatedly on the same site of the specimen, without any operator intervention. The variation within repeated measurements is often due to the statistical nature of the tool signal (e.g., SEM signal) and the interpretation of this signal by the measurement algorithm as implemented in the recipe. Reproducibility, on the other hand, refers to the consistency of measurement results obtained from different sites of the same pattern on the specimen, potentially at different times. Reproducibility accounts for sources of variation such as wafer alignment, SEM autofocus, pattern recognition, tool stability, and other factors that can impact measurement consistency across multiple sites. Thus, in overlay measurements, precision may reflect not only the repeatability of measurements obtained at a single site, but also the reproducibility of measurements collected from several sites of the same pattern across the wafer.

Evaluating precision traditionally requires the acquisition of extensive datasets, involving repeated imaging at multiple sites under varied configurations. However, the acquisition of such extensive datasets is time-consuming and resource-intensive. Additionally, the evaluation process conventionally requires executing the target algorithm on the acquired datasets to assess its performance metrics, which consumes substantial computational resources. As a result, such image acquisition and algorithm evaluation processes unavoidably limit the range of recipe or algorithm configurations that can be tested within the constraints of limited tool time, hindering the ability to explore and optimize various configurations, and achieve optimal examination performance.

Accordingly, to address these challenges, certain embodiments of the presently disclosed subject matter propose a computerized system and method for predicting algorithm performance without the need for executing the algorithms on extensive datasets. Instead, the present disclosure leverages a variation model that can translate the content and attributes of acquired images into predictions of algorithm performance metrics. By analyzing a set of image attributes, the variation model is capable of predicting how the target algorithm would respond to changes or variations in these attributes. This approach significantly reduces the dependency on large datasets and tool time, while enabling the testing and optimization of a wider range of algorithm configurations, as will be detailed below.

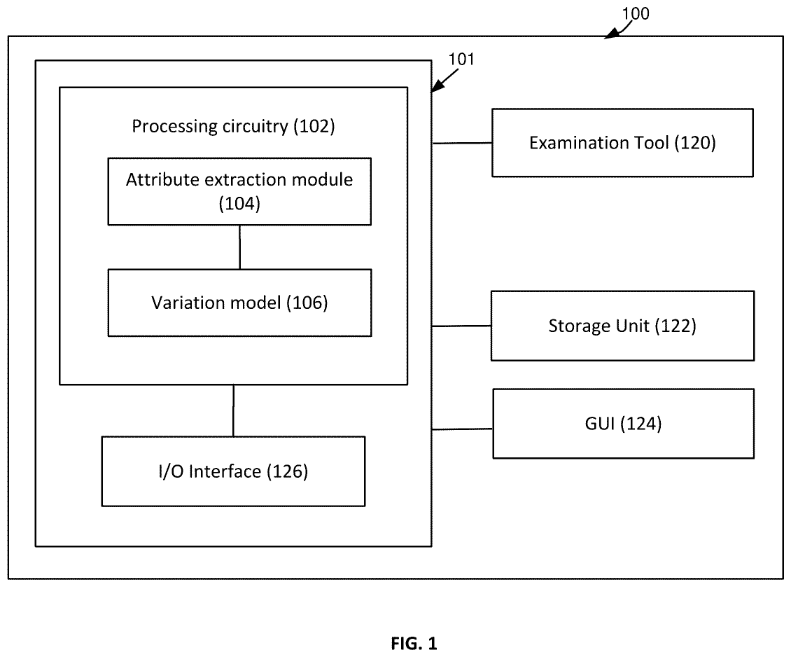

Bearing this in mind, attention is drawn to FIG. 1 illustrating a functional block diagram of an examination system in accordance with certain embodiments of the presently disclosed subject matter.

The examination system 100 illustrated in FIG. 1 can be used for examination of a semiconductor specimen (e.g., a wafer, a die, or parts thereof) as part of the specimen fabrication process. As described above, the examination referred to herein can be construed to cover any kind of operations related to metrology operations, and/or defect examination operations such as, e.g., defect inspection/detection, defect review, defect classification, nuisance filtration, etc., with respect to the specimen. System 100 comprises one or more examination tools 120 configured to scan a specimen and capture images thereof to be further processed for various examination applications.

The term “examination tool(s)” used herein should be expansively construed to cover any tools that can be used in examination-related processes, including, by way of non-limiting example, scanning (in a single or in multiple scans), imaging, sampling, reviewing, measuring, classifying, and/or other processes provided with regard to the specimen or parts thereof. Without limiting the scope of the disclosure in any way, it should also be noted that the examination tools can be implemented as inspection machines of various types, such as optical inspection machines, electron beam inspection machines (e.g., a Scanning Electron Microscope (SEM), an Atomic Force Microscopy (AFM), or a Transmission Electron Microscope (TEM), etc.), and so on.

In some embodiments of the present disclosure, at least one of the examination tools 120 has metrology capabilities and can be configured to capture images and perform metrology operations on the captured images. Such an examination tool is also referred to as a metrology tool.

One example of a metrology tool used within the examination system is a Critical Dimension Scanning Electron Microscope (CD-SEM). CD-SEM is a specialized tool designed to capture high-resolution images of semiconductor structures and perform precise dimensional measurements on those structures, typically at the nanoscale. In the present disclosure, the CD-SEM captures detailed images of critical features/patterns on the modulated wafer, enabling accurate measurements of the features' dimensions under varying process window conditions. The CD-SEM can be used to obtain critical dimension (CD) measurements with respect to certain structural features on the specimen to determine if they meet the design specifications across different focus and exposure settings. Additionally, the CD-SEM's metrology capabilities can be leveraged to measure critical metrics between layers, such as critical distances, to assess whether these dimensions remain within acceptable limits.

In some embodiments, optionally, in addition to or in lieu of the metrology tool, the one or more examination tools 120 can include one or more inspection tools and/or one or more review tools. In some cases, an inspection tool can be configured to scan the specimen to capture inspection images (typically, at a relatively high-speed and/or low-resolution) for detection of potential defects (i.e., defect candidates). During inspection, the wafer can move at a step size relative to the detector of the inspection tool (or the wafer and the tool can move in opposite directions relative to each other) during the exposure, and the wafer can be scanned step-by-step along swaths of the wafer by the inspection tool, where the inspection tool images a part/portion (within a swath) of the specimen at a time. By way of example, the inspection tool can be an optical inspection tool. At each step, light can be detected from a rectangular portion of the wafer and such detected light is converted into multiple intensity values at multiple points in the portion, thereby forming an image corresponding to the part/portion of the wafer. For instance, in optical inspection, an array of parallel laser beams can scan the surface of a wafer along the swaths. The swaths are laid down in parallel rows/columns contiguous to one another, to build up, swath-at-a-time, an image of the surface of the wafer. For instance, the tool can scan a wafer along a swath from up to down, then switch to the next swath and scan it from down to up, and so on and so forth, until the entire wafer is scanned and inspection images of the wafer are collected.

In some cases, a review tool can be configured to capture review images of at least some of the defect candidates detected by inspection tools for ascertaining whether a defect candidate is indeed a defect of interest (DOI). Such a review tool is usually configured to inspect fragments of the specimen, one at a time (typically, at a relatively low-speed and/or high-resolution). By way of example, the review tool can be an electron beam tool, such as, e.g., a scanning electron microscope (SEM), etc.

The various examination tools can be different tools located at the same or at different locations, or integrated as a single tool operated in different modes. In some cases, the same examination tool can provide low-resolution image data and high-resolution image data. The resulting image data (low-resolution image data and/or high-resolution image data) can be transmitted—directly or via one or more intermediate systems—to system 101. The present disclosure is not limited to any specific type of examination tools and/or the resolution of image data resulting from the examination tools.

According to certain embodiments of the presently disclosed subject matter, the examination system 100 comprises a computer-based system 101 operatively connected to the examination tool 120, and capable of algorithm performance prediction for algorithms usable for examining a semiconductor specimen. System 101 is also referred to as an algorithm performance prediction system.

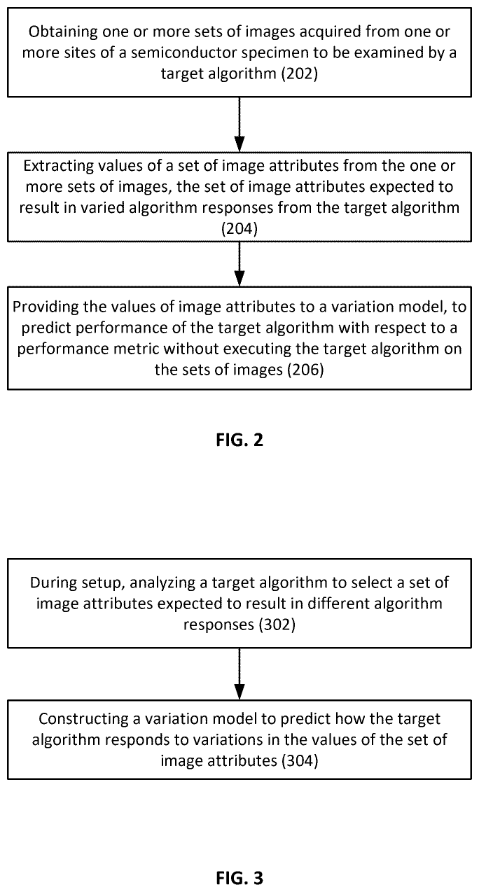

System 101 includes a processing circuitry 102 operatively connected to a hardware-based I/O interface 126 and configured to provide processing necessary for operating the system, as further detailed with reference to FIGS. 2-3. The processing circuitry 102 can comprise one or more processors (not shown separately) and one or more memories (not shown separately). The one or more processors of the processing circuitry 102 can be configured to, either separately, or in any appropriate combination, execute several functional modules in accordance with computer-readable instructions implemented on a non-transitory computer-readable memory comprised in the processing circuitry. Such functional modules are referred to hereinafter as comprised in the processing circuitry.

According to certain embodiments, one or more functional modules comprised in the processing circuitry 102 of system 101 can include an attribute extraction module 104 and a variation model 106 operatively connected to each other.

Specifically, the processing circuitry 102 can be configured to obtain (e.g., via an I/O interface 126, or from the storage unit 122) one or more sets of images acquired (e.g., by the examination tool 120) from one or more sites of a semiconductor specimen to be examined by a target algorithm. The attribute extraction module 104 can be configured to extract values of a set of image attributes from the one or more sets of images. The set of image attributes to be extracted are those expected to result in varied algorithm responses from the target algorithm.

The values of the set of image attributes can be provided to the variation model 106, to predict performance of the target algorithm with respect to a performance metric without executing the target algorithm on the sets of images. The variation model 106 is constructed during setup to predict how the target algorithm responds to variations/changes of values of the set of image attributes.

It is to be noted that while certain embodiments of the present disclosure refer to the processing circuitry 102 being configured to perform the above recited operations, the functionalities/operations of the aforementioned functional modules can be performed by the one or more processors in processing circuitry 102 in various ways. By way of example, the operations of each functional module can be performed by a specific processor, or by a combination of processors. The operations of the various functional modules, such as the attribute extraction, and the algorithm performance prediction, etc., can thus be performed by respective processors (or processor combinations) in the processing circuitry 102, while, optionally, these operations may be performed by the same processor. The present disclosure should not be limited to being construed as one single processor always performing all the operations.

In some cases, additionally to system 101, the examination system 100 can comprise one or more examination modules, such as, e.g., defect detection module, nuisance filtration module, Automatic Defect Review Module (ADR), Automatic Defect Classification Module (ADC), metrology operation module, and/or other examination modules which are usable for examination of a semiconductor specimen. The one or more examination modules can be implemented as stand-alone computers, or their functionalities (or at least part thereof) can be integrated with the examination tools 120. In some cases, the output of system 101, e.g., the performance prediction, can be provided to the one or more examination modules for further processing.

According to certain embodiments, system 100 can comprise a storage unit 122. The storage unit 122 can be configured to store any data necessary for operating system 101, e.g., data related to input and output of system 101, as well as intermediate processing results generated by system 101. By way of example, the storage unit 122 can be configured to store the one or more sets of images and/or derivatives thereof produced by the examination tool 120, as well as the pre-constructed variation model, as described above. Accordingly, the input data as required can be retrieved from the storage unit 122 and provided to the processing circuitry 102 for further processing. The output of the system 101, such as, e.g., the performance prediction, can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the specimen (for example, by a display forming part of GUI 124), including the images of the specimen, etc. The user may be provided, through the GUI, with options of defining certain operation parameters. The user may also view the operation results or intermediate processing results, such as, e.g., the performance prediction, etc., on the GUI.

In some cases, system 101 can be further configured to send, via I/O interface 126, the operation results to the examination tools 120 for further processing. In some cases, system 101 can be further configured to send the results to the storage unit 122, and/or external systems (e.g., Yield Management System (YMS) of a fabrication plant (fab)). A yield management system (YMS) in the context of semiconductor manufacturing is a data management, analysis, and tool system that collects data from the fab, especially during manufacturing ramp-ups, and helps engineers find ways to improve yield. YMS helps semiconductor manufacturers and fabs manage high volumes of production analysis with fewer engineers. These systems analyze the yield data and generate reports. YMS can be used by Integrated Device Manufacturers (IMD), fabs, fabless semiconductor companies, and Outsourced Semiconductor Assembly and Test (OSAT).

Those versed in the art will readily appreciate that the teachings of the presently disclosed subject matter are not bound by the system illustrated in FIG. 1. Each system component and module in FIG. 1 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 1.

Each component in FIG. 1 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

It should be noted that the examination system illustrated in FIG. 1 can be implemented in a distributed computing environment, in which one or more of the aforementioned components and functional modules shown in FIG. 1 can be distributed over several local and/or remote devices. By way of example, the examination tool 120 and the system 101 can be located at the same entity (in some cases hosted by the same device) or distributed over different entities, depending on specific system configurations and implementation needs.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

It should be further noted that in some embodiments at least some of examination tool 120, storage unit 122 and/or GUI 124 can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more examination tools 120, thereby facilitating and enhancing the functionalities of the examination tools in examination-related processes.

While not necessarily so, the process of operations of systems 101 and 100 can correspond to some or all of the stages of the methods described with respect to FIGS. 2-3. Likewise, the methods described with respect to FIGS. 2-3 and their possible implementations can be implemented by systems 101 and 100. It is therefore noted that embodiments discussed in relation to the methods described with respect to FIGS. 2-3 can also be implemented, mutatis mutandis as various embodiments of the systems 101 and 100, and vice versa.

Referring to FIG. 2, there is illustrated a generalized flowchart of algorithm performance prediction for an algorithm usable for examining a semiconductor specimen in accordance with certain embodiments of the presently disclosed subject matter.

As described above, a semiconductor specimen is typically made of multiple layers. The examination process of a specimen can be performed a multiplicity of times during the fabrication process of the specimen, for example following certain processing steps of specific layers. For the purpose of illustration only, certain embodiments of the following description are described with respect to an algorithm usable for examining a given processing step/layer of the specimen. Those skilled in the art will readily appreciate that the teachings of the presently disclosed subject matter can be performed for any layer and/or processing steps of the specimen. The present disclosure should not be limited to the number of processing steps/layers comprised in the specimen and/or the specific layer(s) to be examined.

One or more sets of images can be obtained (202) (e.g., by the processing circuitry 102 from the examination tool 120). The one or more image sets can be acquired from one or more sites of a semiconductor specimen to be examined by a target algorithm. The images can result from various examination tools of different examination modality(s), such as, e.g., by an optical inspection tool, an electron beam tool, etc., and the present disclosure is not limited by the specific examination modality used for acquiring the images.

By way of example, the image sets may be captured by a scanning electron microscope (SEM) tool, with each image capturing a feature of interest (FOI) on a site of the specimen. As described above, the target algorithm can vary, depending on the specific applications. By way of example, in some cases, the target algorithm can be a metrology algorithm usable in metrology applications, while in some other cases, the target algorithm can be a defect detection or review algorithm usable in defect examination applications.

A feature of interest (FOI), also referred to as a target feature, can include any structure or pattern on the semiconductor specimen that is of interest to be examined in the examination process. It can vary, depending on the nature of the target algorithm and the specific semiconductor examination application. By way of example, in metrology applications, where the target algorithm may be a critical dimension (CD) algorithm or an overlay algorithm, FOIs can typically include target features to be measured. For instance, in overlay measurements, an FOI may include a pair of features/structures located on two different layers of the wafer, such as trenches or lines, used to calculate misalignment. In CD measurements, the FOIs may include features such as, e.g., lines, contact holes, etc., where the dimensions of line widths, spaces between lines, or the diameters of contact holes are to be measured to ensure compliance with design specifications.

By way of another example, in defect examination applications, where the target algorithm may be used for defect detection, review, or classification, FOIs may represent defect candidates identified on the specimen. These FOIs may indicate anomalies or deviations from expected patterns, such as particles, scratches, bridging defects, or voids, etc. The FOIs in such cases may be critical for determining the presence, type, and/or potential impact of defects on the overall yield and functionality of the semiconductor device.

In some embodiments, a single set of images may be acquired from one site on the specimen that contains the FOL. For example, in a metrology application, an image may capture a target feature, such as a line pattern located on a specific layer of the wafer, for evaluating a CD or overlay algorithm. In other cases, a plurality of sets of images may be captured from multiple sites on the specimen, where each site contains the same FOL. These sites may correspond to the same relative locations within different dies on the wafer. Similarly, in defect examination applications, images may be acquired from one or more sites of a wafer based on a defect map indicative of defect candidate distribution across the wafer.

A set of values for a set of image attributes can be extracted (204) (e.g., by the attribute extraction module 104 in the processing circuitry 102) from the one or more sets of images. By way of example, the set of image attributes can comprise a subset of value attributes (such as, e.g., contrast, resolution, gray level (GL) profiles, image zones/regions, etc.) and a subset of statistical attributes (such as, e.g., noise statistics) derived from the one or more sets of images. The set of image attributes can be specifically defined/selected as those expected to result in varied algorithm responses from the target algorithm. In some cases, the set of image attributes can be predetermined during setup, as described below in further detail with respect to FIG. 3.

The values of the set of image attributes can be provided (206) to a variation model (e.g., the variation model 106 in the processing circuitry 102), to predict performance of the target algorithm with respect to a performance metric without having to execute the target algorithm on the sets of images.

By way of example, in cases where the target algorithm is a metrology algorithm, the performance metric can be precision, which is indicative of repeatability of metrology measurements obtained from the semiconductor specimen. The variation model can be constructed, e.g., during setup, to predict how the target algorithm responds to variations/changes of values of the set of image attributes, as described below in further detail with respect to FIG. 3.

FIG. 3 illustrates a generalized flowchart of setup phase procedures in accordance with certain embodiments of the presently disclosed subject matter.

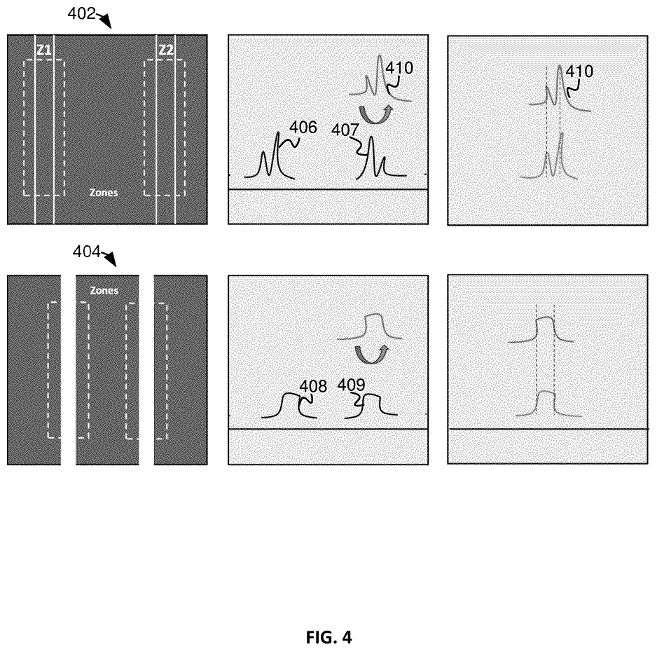

During setup, the target algorithm can be analyzed (302) to select a set of image attributes that are expected to result in different algorithm responses. This step involves a detailed examination of the algorithm's structure, functionality, and operational characteristics. The goal is to determine which attributes of the input images have the most significant impact on the algorithm's output. For example, in an overlay algorithm, attributes such as gray level (GL) profiles, resolution, and symmetry of features in the regions of interest (ROIs) may play critical roles in determining the correlation peak and subsequent overlay measurement, as will be described below in further detail with reference to FIGS. 4-7. In a CD algorithm, attributes such as contrast, edge sharpness, and spacing between features relative to resolution are likely to influence the repeatability of dimension measurements.

The analysis in step 302 can be guided by a combination of mathematical modeling and physical principles underlying the target algorithm. Mathematical analysis may involve studying the algorithm's processing functions, such as convolution or feature extraction, to understand how variations in image attributes propagate through the algorithm. Physical analysis may focus on the imaging modality (e.g., SEM or optical imaging) and the specimen's characteristics to determine how these influence image quality and, consequently, the algorithm's output.

Based on the insights gained from the analysis, a set of image attributes can be selected. This set typically includes value attributes (e.g., resolution, contrast, or ROI definitions) that represent intrinsic image properties, as well as statistical attributes (e.g., noise statistics) that capture the randomness or variability in the image data. These attributes form the foundation for constructing the variation model.

After selecting the relevant image attributes, the variation model can be constructed (304) to predict how the target algorithm responds to variations/changes in the values of the set of image attributes. In constructing the model, relationships between the attributes and the algorithm's output variations are characterized. Output variation refers to the degree of variability or inconsistency in the results or measurements produced by a target algorithm when applied to a given set of input data (e.g., images acquired from a semiconductor specimen). Output variation is typically quantitatively described by statistical measures that characterize the distribution of the algorithm's output results. These statistics capture to which extent the outputs deviate from a mean or expected value, and provide insights into the algorithm's performance, such as precision or accuracy. By way of example, for a target overlay algorithm, output variation could represent the variability in overlay measurements across different image acquisitions of the same or different sites on the semiconductor wafer. For instance, the model may predict how noise statistics affect the likelihood of deviations in overlay measurements.

In some embodiments, the variation model is constructed to predict a relationship between output variations of the target algorithm and the statistical attributes (e.g., noise statistics). This relationship is modeled to reflect the algorithm's sensitivity to input noise and variability. The variation model captures the relationship by establishing a dependency on the multi-dimensional attribute space defined by the selected value attributes. Each dimension in this space corresponds to a specific value attribute (e.g., resolution or symmetry), and the model uses the position within this space to parameterize its predictions. Thus, this relationship is parameterized by the position in the multi-dimensional attribute space. For example, at a position in the attribute space corresponding to high resolution, the model may predict smaller output variations due to reduced sensitivity to noise. Conversely, at a position representing low resolution or asymmetric ROIs, the model may predict larger output variations due to increased sensitivity to image variability.

Statistical measures, such as, e.g., the Tool induced shift (TIS) 3σ, can be used to capture and quantify the output variation. TIS 3σ estimation is a common metric in metrology that quantifies the range within which most output variations fall, assuming a normal distribution. TIS 3σ estimation is often used to characterize precision, as it encompasses 99.7% of the data points in a Gaussian distribution.

The setup phase concludes with a fully constructed variation model that is tailored to the specific characteristics of the target algorithm. This model forms the foundation for accurately predicting algorithm performance in the operational phase in runtime. The constructed model enables the prediction of algorithm performance metrics, such as precision, based on input image attributes, thereby eliminating the need for exhaustive execution of the target algorithm during performance evaluation.

For purpose of illustration, an overlay algorithm is described below as an example of a target algorithm used in an overlay application, to demonstrate the setup process for image attribute extraction and variation model construction. This example illustrates how specific image attributes, such as gray level (GL) profiles and noise statistics, are extracted and used to analyze the algorithm's responses, ultimately enabling precise performance predictions.

An overlay algorithm is usable for obtaining overlay measurement between two layers, e.g., between a first layer and a second layer in the semiconductor specimen. Overlay measurements are critical for ensuring proper alignment of layers, which directly impacts the functionality and yield of semiconductor devices. In such cases, each set of images acquired from a respective site on the specimen can comprise one or more images for each layer. For instance, for a given site, the SEM tool may repetitively capture a sequence of images capturing the feature of interest (FOI) in that site. If there are two layers at that site, the set of images would include a sequence of images corresponding to the FOI on the first layer, and a separate sequence of images corresponding to the FOI on the second layer. The sequence of images can include multiple images or, in specific cases, a single image for each layer, depending on the imaging requirements and conditions. For example, for the first layer, the SEM tool may capture one or more secondary electron (SE) images as the sequence of images for the first layer. This ensures that sufficient image data is collected to evaluate alignment and measure overlay between the layers with high precision.

For instance, a first image of a first structure on the first layer and a second image of a second structure on the second layer of a specimen can be acquired. In some cases, the first layer and the second layer can refer to two successive physical layers of the semiconductor specimen. The first structure on the first layer and the second structure on the second layer can refer to two structural features formed successively on the two layers with expected relative positions. These positions are defined by the design specifications of the semiconductor device. In some other cases, the first layer and the second layer can refer to two processing steps within the same physical layer. The first structure on the first layer and the second structure on the second layer can refer to two structures (as part of a structural feature) formed on the same layer via two or more different processing steps (also referred to as multi-patterning).

In some cases, the first image and the second image can be the same image. For instance, one image acquired by a metrology tool may be representative of both the first structure and the second structure. In some other cases, the first image and the second image can be different images. By way of example, the first image and the second image can be two different images acquired by an electron beam tool, such as a SEM tool. The SEM tool used herein can be, e.g., critical dimension scanning electron microscopes (CD-SEM) configured to perform metrology operations with respect to structural features of a specimen based on the captured images. In one example, the first image can be a secondary electron (SE) image, and the second image can be a backscattered electron (BSE) image, as described below in further detail.

When an electron beam of SEM strikes a specimen, different types of signals are generated. These signals provide distinct and complementary information on the specimen. Secondary electrons (SEs) originate from the surface or the near-surface regions of the specimen. They are a result of inelastic interactions between the primary electron beam and the specimen, and have lower energy than the backscattered electrons. The shallow depth of production of detected SEs makes them ideal for examining topography of the specimen's surface.

Additionally, backscattered electrons (BSEs) are reflected back after elastic interactions between the beam and the specimen. This type of electron originates from a broad region within the interaction volume. These electrons provide deeper insights into the material properties of the specimen. They are a result of elastic collisions of electrons with atoms, which result in a change in the electrons' trajectory. These essentially elastically scattered primary electrons (which are high-energy electrons) that rebound from the sample, are referred to as BSEs.

As described, BSEs come from deeper regions of the sample, while SEs originate from surface regions. Therefore, BSEs and SEs carry different types of information. This distinction is leveraged in overlay algorithms to provide both surface and sub-surface alignment information. For instance, BSE images show high sensitivity to differences in atomic number, therefore can carry information on the specimen's interior structure and/or composition (i.e., this is referred to as the see-through ability of the BSEs to probe the specimen in depth when provided with enough landing energy), whereas SE images can provide more detailed surface information.

Continuing with the above example, assume the first layer is an upper layer manufactured on top of the second layer which is a lower layer. The first image can be an SE image acquired based on the collected SE signals representative of the upper layer structure, and the second image can be a BSE image acquired based on the collected BSE signals representative of the lower layer structure. The SE image and the BSE image are acquired simultaneously by respective detectors of the SEM tool.

FIG. 4 illustrates an example of a pair of images acquired for two layers in accordance with certain embodiments of the presently disclosed subject matter.

As shown, a first image 402 and a second image 404 of a specimen are acquired. The two images respectively capture a first structure and a second structure of two layers. Specifically, the first image 402 can be a SE image representing an upper layer structure, such as two outer lines illustrated in the image, while the second image 404 can be a BSE image representing a lower layer structure, such as two inner lines.

Regions of interest (ROIs), also referred to as zones, are specific areas on the acquired images that are defined to isolate and focus analysis on the relevant features or structures necessary for executing the overlay algorithm. The definition of ROIs may depend on factors such as the size and geometry of the first and second structures, the relative positions, and the specific requirements of the overlay algorithm, etc. For instance, a pair of first ROIs Z1 and Z2 (as marked by dashed lines) are defined in first image 402, enclosing at least part of the first structure in the first image. Similarly, a pair of second ROIs are defined in second image 404, enclosing at least part of the second structure in the second image. These ROIs can be defined to enable accurate identification of the center of symmetry (COS) (also referred to as center of gravity (COG) in some cases) of the respective structures with respect to the defined regions.

The structures enclosed in the ROIs can be projected to obtain the gray level profiles thereof. The projection can be one dimensional (1D) or two-dimensional (2D), depending on various factors such as the structural complexity and dimensionality of the structure information enclosed in the ROI, and whether the required measurement is along a single axis or in both axes. By way of example, the two structures illustrated in images 402 and 404 can be regarded as comprising mirror-symmetric patterns. As the structure information enclosed in the ROIs indicates a singular dimensionality, i.e., the enclosed structures exhibit uniformity along the Y axis, a 1D projection can be used to extract the representative GL profile along the X direction. For instance, a pair of GL profiles 406 and 407, represented as waveform signals, are extracted for the part of the first structure enclosed in the first ROIs Z1 and Z2 along the X direction, e.g., by averaging the GL values within the first ROIs along the Y direction. Similarly, a pair of GL profiles 408 and 409 are extracted for the part of the second structure enclosed in the second ROIs 404 along the X direction, e.g., by averaging the GL values within the second ROIs along the Y direction.

The COS of the first and second structures can be determined based on the GL profiles. By way of example, the COS of the first structure can be identified through a correlation analysis between the GL profile 406 and a symmetrically rotated profile 410 of the GL profile 407, as illustrated in FIG. 4. For instance, in cases where the pair of GL profiles are representative of a set of mirror-symmetric structures, a symmetrically rotated profile refers to a flipped GL profile (flipped along the central line of the ROI) of the original GL profile. In cases where the pair of GL profiles are representative of a set of rotation-symmetric structures, the symmetrically rotated profile refers to a 180-degree rotated signal of the original GL profile (rotated around the central point of the ROI). Similarly, the COS of the second structure can be identified in the same manner using its corresponding GL profile.

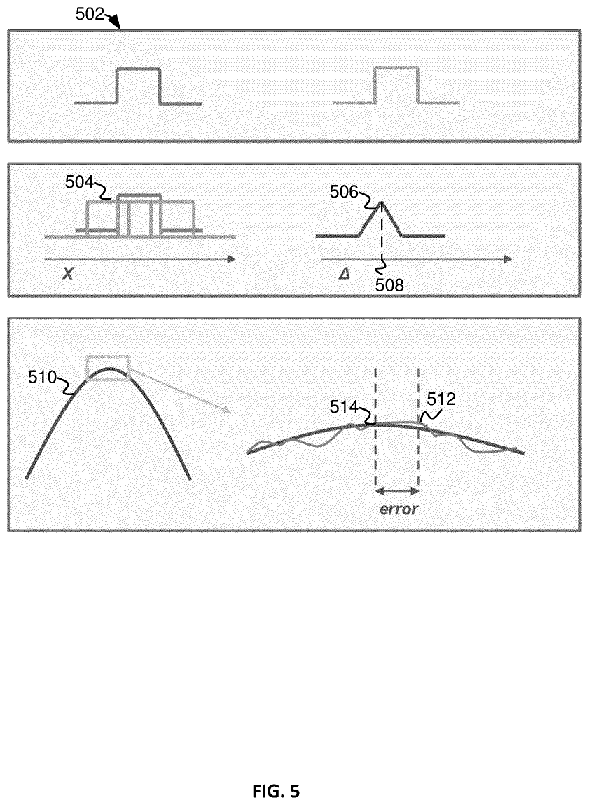

For improved clarity, FIG. 5 provides a schematic illustration of the COS identification process in accordance with certain embodiments of the presently disclosed subject matter.

For a pair of GL profiles 502 extracted for enclosed structures in ROIs of a given layer, as the enclosed structures are mirror-symmetric, the COS can be identified as described above, by performing correlation between the first GL profile and a flipped profile of the second GL profile in the pair. For instance, as illustrated in 504, the flipped profile of the second profile can be shifted incrementally along the X direction relative to the original first GL profile. The correlation values at each position are calculated, to obtain a correlation graph 506. The correlation process can be implemented using various methods, such as convolution or cross-correlation, depending on the specific algorithm requirements. The COS can be identified at a position 508 on the X-axis where the correlation between the flipped and original profiles reaches its maximum/peak, according to the correlation graph 506.

The position 508 on the X axis where the peak correlation is identified corresponds to a shift between the first GL profile and the flipped counterpart. This shift is double the actual displacement of the COS due to the symmetry of the structures. For instance, the position 508 on the X axis represents a shift Δ₁ that the flipped profile moved relative to the first profile, which is twice of the actual shift of the COS. Therefore, the COS δ₁ of the enclosed structures in the ROIs can be derived as: δ₁=Δ₁/2.

Similarly, the COS δ₂ of another layer can be derived in the same manner as: δ₂=Δ₂/2. Once the COSs for the two structures of the two layers are identified, the overlay measurement can be determined. By way of example, the overlay measurement between the first layer and the second layer OVL₁₂ can be derived as:

$${OVL}_{12} = {δ}_{2} - {δ}_{1} .$$

It is to be noted that the GL profile and the correlation map illustrated in 502, 504, and 506 are simplified representations provided solely for purpose of demonstrating the process. In practice, the presence of noises in the acquired images is likely to introduce variations or fluctuations to an otherwise clean correlation graph. By way of example, as illustrated in FIG. 5, the peak of a clean correlation graph 510 can exhibit noise-induced “bumps” that deviate/fluctuate from the smooth curve of the graph. If one such bump is large enough, such as the one illustrated at position 512, it may surpass or overtake the true peak at position 514. This can lead to an incorrect identification of the correlation peak (e.g., the bump at position 514 can be incorrectly identified as the correlation peak), ultimately causing errors in determining the center of symmetry (COS) and, consequently, errors in the output of the overlay algorithm—namely, the overlay measurement.

As can be inferred from the correlation graph, the curvature of the graph/curve around the correlation peak (e.g., how sharp or steep the curve is near the peak, or in other words, how fast the curve decreases from the peak) is directly related to the graph's sensitivity to noise. For instance, a steeper curvature indicates reduced sensitivity to noise, making it less likely for noise at a given distance from the “real” peak to overtake and create a “false peak”. Conversely, a flatter curvature increases sensitivity, raising the probability of noise-induced error per distance, where the distance refers to the position offset from the true peak.

This curvature is defined/influenced by certain image attributes, such as the subset of value attributes mentioned earlier. In the present example, curvature can be affected by value attributes such as, e.g., resolution, the definition and size of regions of interest (ROIs), the number and strength of edges in the ROIs, and the symmetry or asymmetry of the structures enclosed within the ROIs, etc. For instance, better image resolution (i.e., shaper image) generally results in a correlation graph with a sharper peak (i.e., stronger curvature) which is more immune to noise. On the other hand, if the enclosed structures in a pair of ROIs (e.g., Z1 and Z2) exhibit asymmetry (e.g., the structures in the two ROIs have some pattern variations one from the other), the correlation graph may become less sharp (i.e. weaker curvature) and more sensitive to noise.

In some cases, optionally, the curvature can be additionally impacted by statistical image attributes, such as noise statistics within the images. For example, increased noise levels can add additional asymmetry between the two profiles, as the image noise is random and by definition asymmetric between the two profiles, thereby reducing the sharpness of the correlation peak. Together, these value attributes (and, in some cases, together with certain statistical attributes) define a position within a multi-dimensional attribute space.

The interplay between the statistical attributes (e.g., noise statistics) and the value attributes (e.g., resolution, symmetry, and ROI definitions) has a significant impact on the behavior of the target algorithm and the resulting variations in its output. As described above, the value attributes collectively define a position within a multi-dimensional attribute space, where each dimension corresponds to a specific value attribute. The relationship between the statistical attributes and the variation/error in the algorithm's output is inherently dependent on this position within the attribute space. For example, at a position defined by high-resolution and symmetric ROI structures, the correlation graph may exhibit a sharper curvature, resulting in reduced sensitivity to noise, and consequently smaller variation in the output. Conversely, at a position defined by lower resolution or asymmetric ROIs, the curvature may become less steep, increasing the sensitivity to noise and amplifying variations in the algorithm's output.

To account for these dependencies, in some embodiments the variation model can be constructed to predict how changes in the statistical attributes influence the statistics of the variations in the algorithm's output, given the specific position in the multi-dimensional attribute space defined by the subset of value attributes. By analyzing and modeling this relationship, the variation model enables accurate prediction of the algorithm's performance metrics, such as precision for overlay measurements, without requiring exhaustive algorithm execution on large datasets. The predictive capability of the variation model ensures that it captures the intricate dependencies between value attributes, statistical attributes, and the resulting output variations, for evaluating algorithm performance across diverse imaging conditions and configurations.

As previously mentioned, incorrect identification of the correlation peak due to noise can lead to errors in the overlay algorithm's output, namely the overlay measurement. Because this output error is associated with the image noise, given the curvature of the correlation graph, it is desirable to quantify the statistics of this error (also referred to as a statistical error) with respect to the noise statistics in the images. This statistical error reflects the probability of noise surpassing the correlation maximum at different positions relative to the peak. For instance, an error function can be used to calculate the probability of noise surpassing the correlation peak at each delta distance (radius) from the peak's position.

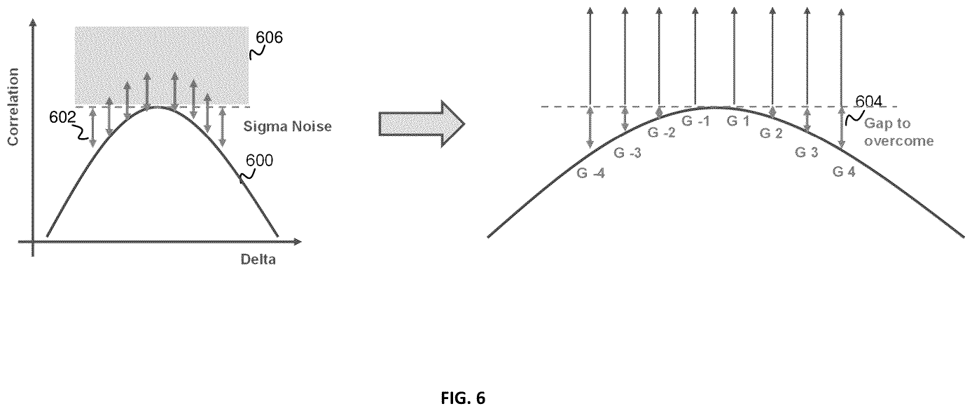

FIG. 6 shows a schematic illustration of calculating the probability of noises surpassing the correlation maximum of a correlation graph in accordance with certain embodiments of the presently disclosed subject matter.

As shown, a clean correlation graph 600, represented as a Gaussian distribution, is plotted, where the x-axis corresponds to the delta distance relative to the correlation peak, and the y-axis corresponds to the correlation strength at each delta position. Vertical arrows 602 indicate the correlation noise (marked as sigma noise), which represents the noise converted into correlation terms derived from statistical attributes such as noise statistics, and the signal profiles.

By way of example, the correlation graph 600, per delta distance from the correlation peak, can be expressed as follows:

$$Corr ( Δ ) = {\sum }_{x} WF 1 ( x ) \cdot WF 2 ( x + Δ ) = {\sum }_{x} ( F 1 ( x ) + N 1 ( x ) ) \cdot ( F 2 ( x + Δ ) + N 2 ( x + Δ ) ) = {\sum }_{x} F 1 ( x ) F 2 ( x + Δ ) + {\sum }_{x} F 1 ( x ) N 2 ( x + Δ ) + {\sum }_{x} F 2 ( x + Δ ) N 1 ( x ) + {\sum }_{x} N 1 N 2 ( Δ )$$

where WF1 and WF2 represent the GL profiles of the two ROIs in the two images, comprising the clean profiles F1 and F2, and the noise N1 and N2 that represent the respective image noises extracted from the two images.

In the above equation, the correlation noise is represented by the below terms:

$${\sum }_{x} F 1 ( x ) N 2 ( x + Δ ) + {\sum }_{x} F 2 ( x + Δ ) N 1 ( x ) + {\sum }_{x} N 1 N 2 ( Δ )$$

where the term Σₓ N1N2(Δ) is often negligible.

Errors occur when the correlation noises surpass the correlation maximum, such as into the region 606 above the correlation maximum. The probability of the noises surpassing the correlation maximum at a given delta position can be calculated based on the correlation noise 602, and the gap 604 (i.e., the difference between the correlation value at the position and the correlation maximum). For instance, the gap 604 at each position can be approximated as: curvature*radius\hat{ }2. The probability at a specific delta position (radiusᵢ) can be calculated as follows:

$$Prob ( {radius}_{i} ) = 0.5 * [ Erf ( inf ) - Erf ( {G}_{i} / 1.414 * correlation\_noise ) ]$$

where the Erf stands for the Gaussian error function, which is a statistical function that estimates the statistical probability of the value of a normally distributed variable to be lower than a given number, and Gi represents the gap at each delta position radiusᵢ.

The overall statistics of the output error, i.e., the statistical error representing variations in overlay measurements, can be represented by summing the product of the probabilities along a range of delta distances relative to the position of the correlation maximum and the respective delta distance, as illustrated in the below function. Note that the probability represented by Prob(radiusᵢ) in the below function refers to the probability density at a specific distance, and the actual probability between position i and i+1 can be represented by the Prob(radiusᵢ) multiplying the “thickness” of the bins, i.e., delta (radius).

$$Statistical Error = {\sum }_{i = - n}^{n} [ Prob ( {radius}_{i} ) * {radius}_{i} ] * delta ( radius )$$

In the present example, the target algorithm is an overlay algorithm, and the output error refers to the error of the overlay measurement resulting from the overlay algorithm. The statistics of the output error reflect the variations in the overlay measurements, which directly impact the precision of the algorithm. The statistics of the output error are thus also referred to as output variations.

As described above, a key performance metric for an overlay algorithm is precision, which indicates the repeatability between independent measurements. For instance, high precision indicates that the overlay measurements are repeatable, meaning the measurements exhibit small variance, and the distribution of outputs is relatively tight. Therefore, the statistical error that represents the variations of the overlay measurements can serve as a predictor for the overlay algorithm's performance with respect to precision.

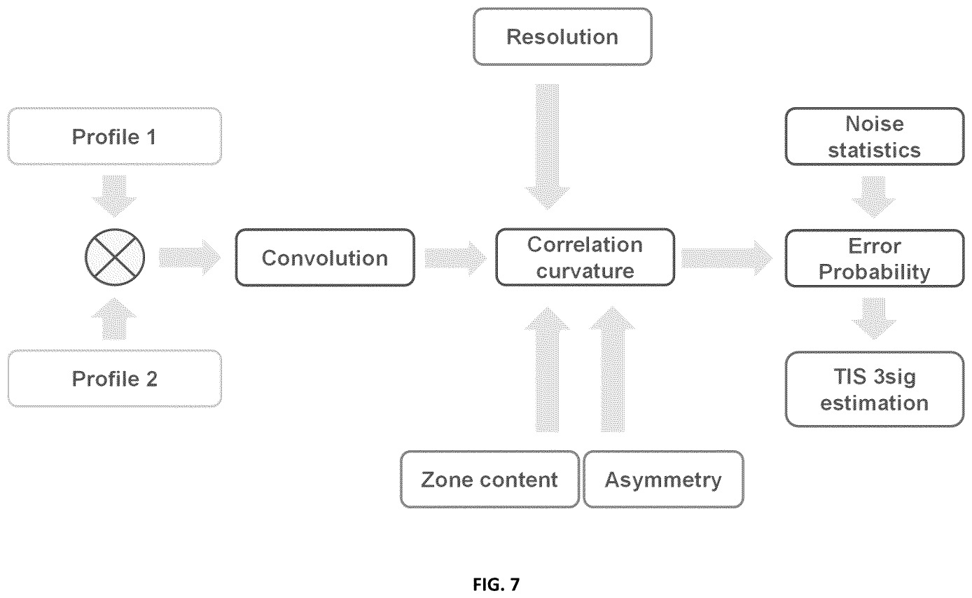

To demonstrate the process of performance prediction in a clear and structured manner, FIG. 7 illustrates a schematic block diagram of the performance prediction process for an overlay algorithm in accordance with certain embodiments of the presently disclosed subject matter.

As shown in FIG. 7, the process begins with a pair of gray-level (GL) profiles, labeled “Profile 1” and “Profile 2,” which correspond to a pair of features enclosed within a pair of regions of interest (ROIs) in a given image. These profiles represent the GL distribution of the features and are used to calculate the correlation between the two profiles. The correlation process, which may be performed using convolution or similar techniques, produces a correlation graph. This graph is central to determining the COS between the two features and is sensitive to various image attributes.

Several value attributes, represented in the figure as separate blocks, such as “Resolution,” “Zone Content” (representing the enclosed structures within the ROIs), and “Asymmetry”, influence the curvature of the correlation graph. These attributes are extracted from the GL profiles and provided as inputs to the “Correlation Curvature” block. The correlation curvature describes the sharpness of the correlation graph around its peak, with sharper curves being less sensitive to noise and less likely to exhibit errors caused by noise-induced bumps. These value attributes collectively define a position in a multi-dimensional attribute space, which parameterizes the prediction process.

In addition to the value attributes, statistical attributes such as noise statistics extracted from the images, are also considered. Noise statistics quantify the variability or randomness present in the images, which directly affects the likelihood of noise surpassing the correlation maximum. These statistical attributes, together with the correlation curvature, are provided as inputs to the “Error Probability” block, which calculates the probability of noise surpassing the true correlation peak at various delta positions, as described in earlier sections.

The “Error Probability” block outputs the noise-induced probability distribution, which is then used in the “TIS 3σ Estimation” block. The TIS 3σ estimation block integrates the probabilities along a range of delta distances from the correlation maximum to calculate the overall statistics of the output variation, referred to as the statistical error. This statistical error reflects the variations in overlay measurements and serves as the predicted performance metric (e.g., precision) for the overlay algorithm.

Therefore, in some cases, the variation model described above can be regarded as comprising the components represented by the blocks Correlation Curvature, Error Probability, and TIS 3σ Estimation. These blocks together perform the task of predicting the overlay algorithm's output variations based on the input attributes.

The inputs to the variation model in the present example include a set of image attributes, which comprises the pair of GL profiles representing a value attribute (from which the value attributes such as resolution, zone content, and asymmetry can be derived), and noise statistics, representing a statistical attribute, extracted from each image.

In cases where multiple images are involved, such as secondary electron (SE) and backscattered electron (BSE) images, the described process is applied independently to each image. Specifically, for each image (e.g., SE and BSE), the GL profiles are analyzed, and the corresponding error probabilities and statistical error predictions are computed separately. The results from the SE and BSE images are then combined to obtain a final prediction for the overlay algorithm's precision. This ensures that the predictions account for the contributions of each imaging perspective.

For instance, the overlay can be measured by subtracting the COS of one image from that of the other image. When looking for the statistical equivalent, e.g.,—a subtraction of two uncorrelated parameters (i.e., two statistical errors from the two images) with normal distribution, the resulting variance of the subtraction is the variance of the 1^{st} parameter (i.e., the statistical error of the first image) plus that of the 2^{nd} parameter (i.e., the statistical error of the second image), and the standard deviation will be the square root of this summation. Specifically, this means that for this case the standard deviation of the overlay measurement would be sqrt (sigma_SE\hat{ }2+sigma_BSE\hat{ }2). This is also referred to as Root Sum Squared (RSS).

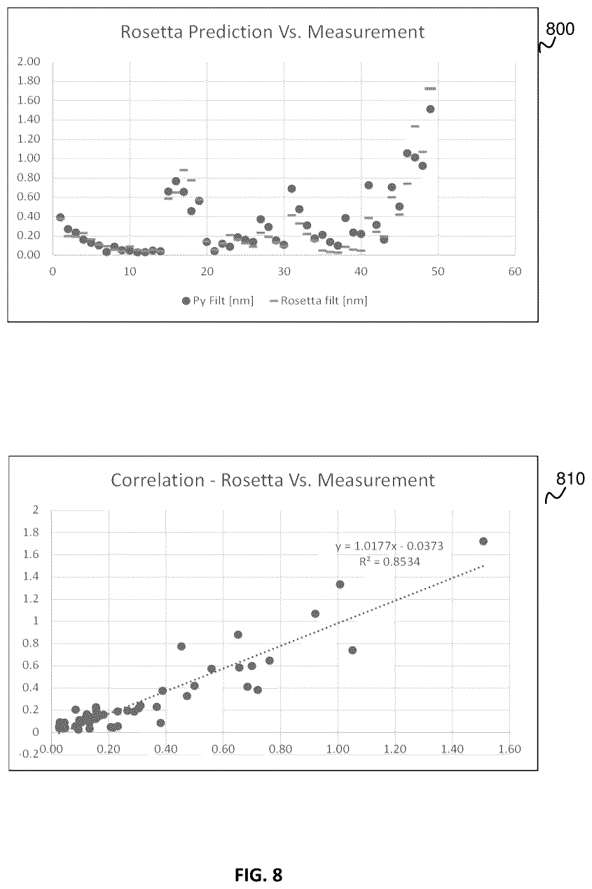

Referring to FIG. 8, there is shown a comparison between the prediction results obtained using the proposed process and the actual measurements derived from executing the overlay algorithm on the image datasets in accordance with certain embodiments of the presently disclosed subject matter. The figure illustrates two sub-images, 800 and 810, that respectively present the consistency between the predicted and actual results and their statistical correlation.

In sub-image 800, the x-axis represents different image datasets, numbered sequentially from 1 to 49. Each dataset corresponds to images acquired from one or more sites on a semiconductor specimen. The y-axis represents the TIS 3σ estimation results, expressed in nanometers (nm), which are indicative of the predicted variations in overlay measurements. The plot shows two sets of data points: the prediction results generated by the proposed variation model are marked with “-”, while the actual results obtained by executing the overlay algorithm on the image datasets are marked with dots “●”.

As illustrated in sub-image 800, the prediction results closely align with the actual measurements for most datasets, indicating strong consistency. This demonstrates the accuracy of the proposed process in predicting overlay algorithm performance without requiring direct execution on large image datasets. Minor deviations observed in some datasets may result from limitations in statistical modeling or unmodeled variations in the dataset itself.

Sub-image 810 provides a statistical correlation analysis between the prediction results and the actual measurements. The x-axis represents the actual measurements, and the y-axis represents the prediction results. The correlation is visually represented by a scatter plot of data points, along with a fitted regression line indicating the degree of correlation. The regression line is described by the equation y=1.0177x−0.0373. The slope of approximately 1.0177 indicates a near-linear relationship, demonstrating that the predictions closely approximate the actual measurements.

Additionally, the coefficient of determination, R²=0.8534, quantifies the goodness-of-fit of the regression line. An R² value of 0.8534 indicates that 85.34% of the variability in the prediction results is explained by the actual measurements, reflecting a strong positive correlation between the two datasets. This further validates the reliability of the proposed prediction process.

The results illustrated in FIG. 8 collectively underscore the effectiveness of the proposed process in predicting overlay algorithm performance. By leveraging the variation model to predict performance metrics such as TIS 3σ estimation, the process minimizes the need for exhaustive execution of the overlay algorithm, thereby optimizing tool time and computational resources. The close correlation between prediction results and actual measurements demonstrates that the proposed approach provides a robust and efficient solution for evaluating and optimizing algorithm performance in semiconductor examination processes.

It is to be noted that although certain embodiments of the present disclosure are described with respect to the overlay algorithm, the proposed prediction process is equally applicable to other algorithms, including other metrology algorithms such as, e.g., critical dimension (CD) algorithms, which are widely used for measuring the dimensions of fine features on a semiconductor specimen. For a CD algorithm, the target performance metric is precision, which refers to the repeatability of independent measurements of critical dimensions (e.g., line widths, spacings, or contact hole diameters) under the same conditions.

By way of example, the set of image attributes relevant to the CD algorithm may include, but are not limited to:
Resolution: The level of detail captured in the images, which directly impacts the clarity of feature edges and the precision of measurements.
Contrast: The difference in intensity between adjacent regions or features in the image, which affects the ability to accurately detect edges and boundaries.
Geometric distortions: caused by either optics and/or wafer charging.
Noise statistics: The degree of randomness or variability in the pixel intensities, which can introduce uncertainties in the edge detection and measurement processes.

For precision prediction in CD measurements, the proposed process involves extracting these attributes from the acquired images and using them as inputs to the variation model. The variation model predicts how changes in these image attributes influence the repeatability of the CD measurements.

The predicted precision, derived from the variation model, serves as an indicator of the CD algorithm's performance. By enabling the prediction of precision without the need for exhaustive execution of the CD algorithm on large datasets, the process allows for efficient evaluation and fine-tuning of CD measurement processes, ensuring accurate and consistent metrology outcomes.

In some other cases, the proposed prediction process can also be applicable to defect examination algorithms, which are used to detect, review, and classify defects in semiconductor specimens. In this case, the target performance metric may be the accuracy of defect detection (e.g., in terms of capture rate, false alarm rate, etc.), which reflects the algorithm's ability to correctly identify and classify true defects, while minimizing false positives and false negatives.

By way of example, for defect examination algorithms, the set of image attributes relevant to performance prediction may include:
Resolution: Higher resolution enhances the visibility of small defects or fine deviations from the expected pattern.
Contrast: Improved contrast aids in distinguishing defects from the background or surrounding structures.
Pattern complexity: The complexity of the background pattern surrounding the defect candidates, which may influence the likelihood of false positives.
Defect characteristics, such as defect size, defect shape, etc.
Noise statistics: Variability in pixel intensities, which can mask or exaggerate defects, impacting detection accuracy.

Similarly, the prediction process involves extracting these attributes from the acquired images and feeding them into the variation model. The model predicts the relationship between these attributes and the accuracy of the defect examination algorithm (in terms of metrics such as capture rate, false alarm rate, etc.). Since some of the defect characteristics may be unknown, in some cases the output of the model may provide a table (or a function) instead of a value, such as e.g., a table where a first column includes several defect characteristics, such as defect sizes (or some other attributes related to the “strength” of the defect), and a second column includes the predicted statistical output for a defect of that type (e.g., a ratio between capture rate and false alarm rate).

By predicting the performance metric (e.g., accuracy) based on image attributes, the proposed process allows for early evaluation and optimization of defect examination configurations, such as adjusting imaging settings or refining algorithm parameters, without the need to run the defect algorithm exhaustively on extensive datasets.

Having described the above algorithms as examples, it is to be noted that the proposed prediction process is not limited to overlay, CD, or defect examination algorithms. The flexibility of the variation model enables its application to various algorithms by defining relevant image attributes and performance metrics specific to each algorithm. This generality ensures that the process provides significant efficiency gains in algorithm evaluation and optimization across diverse semiconductor examination applications.

It is to be noted that examples illustrated in the present disclosure, such as, e.g., the exemplified target algorithms, the image attributes, the examples of acquired images, ROIs and patterns thereof, and the specific equations and calculations for the prediction, etc., are illustrated for exemplary purposes, and should not be regarded as limiting the present disclosure in any way. Other appropriate examples/implementations can be used in addition to, or in lieu of the above.

Among advantages of certain embodiments of the presently disclosed subject matter as described herein, is the ability to predict the performance of a target algorithm without executing the algorithm on extensive image datasets. By leveraging a variation model that analyzes image attributes, such as resolution, contrast, noise statistics, and feature geometry, the present disclosure significantly reduces the time and computational resources required for performance evaluation.

Notably, the proposed solution enables performance prediction based on a much smaller dataset, such as a single image set or a few image sets, due to the use of statistical information extracted from the images. This efficiency enables faster optimization of algorithm configurations and reduces tool time in semiconductor manufacturing processes.

Among further advantages of certain embodiments of the presently disclosed subject matter as described herein, is the capability to provide performance predictions by constructing a variation model that predicts a relationship between the output variations of the target algorithm and the subset of statistical attributes. This relationship is parameterized by a position within a multi-dimensional attribute space, where each dimension is defined by the values of a subset of value attributes, such as resolution or symmetry. By leveraging this parameterization, the proposed solution ensures that performance predictions are tailored to specific imaging conditions and variations in the input data. This adaptability enables the variation model to account for complex dependencies between statistical attributes, value attributes, and algorithm responses, thereby enhancing the accuracy of predictions across a wide range of operational scenarios and supporting robust algorithm optimization.

Among advantages of certain embodiments of the presently disclosed subject matter as described herein, is the ability to account for statistical variations in the output of the target algorithm, such as precision in overlay measurements. By configuring the overlay algorithm based on a correlation graph derived from a pair of gray-level (GL) profiles for each layer, and constructing the variation model to predict the probability of correlation noises surpassing the correlation maximum indicated by the graph, the present disclosure provides an effective means of quantifying statistical error. For example, the statistical error derived from image noise and the curvature of the correlation graph enables detailed prediction of critical performance metrics such as precision. This ensures reliable and repeatable overlay measurements by accounting for the impact of noise and other statistical variations on the correlation analysis.

Among advantages of certain embodiments of the presently disclosed subject matter as described herein, is the flexibility to apply the prediction process to various algorithms, including overlay, CD, and defect examination algorithms. The proposed solution provides a generalized framework for predicting algorithm performance metrics such as precision, or accuracy, depending on the target application. This versatility ensures that the disclosed subject matter is broadly applicable to diverse metrology and inspection workflows in semiconductor manufacturing.

Among advantages of certain embodiments of the presently disclosed subject matter as described herein, is the enhanced utilization of image attributes, such as gray-level profiles and noise statistics, to improve algorithm performance prediction. By extracting these attributes from well-defined regions of interest (ROIs) in the images, the present disclosure ensures precise analysis of features of interest while minimizing the influence of irrelevant image regions. This enables robust predictions even with limited data, leveraging statistical information to generalize algorithm responses effectively.

Among advantages of certain embodiments of the presently disclosed subject matter as described herein, is the ability to improve yield and quality in semiconductor manufacturing by enabling better monitoring and control of critical processes. By providing accurate predictions of algorithm performance, the proposed solution helps optimize the configuration of metrology and inspection tools, ensuring that process deviations are identified and addressed promptly. This contributes to enhanced manufacturing efficiency and reduced defect rates.

It is to be understood that the present disclosure is not limited in its application to the details set forth in the description contained herein or illustrated in the drawings.

In the present detailed description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the present discussions, it is appreciated that throughout the specification discussions utilizing terms such as “obtaining”, “examining”, “extracting”, “providing”, “predicting”, “constructing”, “calculating”, “selecting”, “estimating”, “examining”, or the like, refer to the action(s) and/or process(es) of a computer that manipulate and/or transform data into other data, said data represented as physical, such as electronic, quantities and/or said data representing the physical objects.

The terms “computer”, “computer-based system” or “computerized system” should be expansively construed to cover any kind of hardware-based electronic device with a data processing circuitry (e.g., digital signal processor (DSP), a graphics processing unit (GPU), a field programmable gate array (FPGA), including, by way of non-limiting example, the examination system, the algorithm performance prediction system, and respective parts thereof disclosed in the present application. The data processing circuitry (designated also as processing circuitry) can comprise, for example, one or more processors operatively connected to computer memory, loaded with executable instructions for executing operations, as further described below. The data processing circuitry encompasses a single processor or multiple processors, which may be located in the same geographical zone, or may, at least partially, be located in different zones, and may be able to communicate together.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates including wafers, masks, reticles, and other structures, combinations and/or parts thereof used for manufacturing semiconductor integrated circuits, magnetic heads, flat panel displays, and other semiconductor-fabricated articles. A specimen is also referred to herein as a semiconductor specimen, and can be produced by manufacturing equipment executing corresponding manufacturing processes.

The term “examination” used in this specification should be expansively construed to cover any kind of operations related to defect detection, defect review, and/or defect classification of various types, segmentation, and/or metrology operations during and/or after the specimen fabrication process. Examination is provided by using non-destructive examination tools during or after manufacture of the specimen to be examined. By way of non-limiting example, the examination process can include runtime scanning (in a single or in multiple scans), imaging, sampling, detecting, reviewing, measuring, classifying, and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes (SEM), atomic force microscopes (AFM), optical inspection tools, etc.

The term “metrology operation” used in this specification should be expansively construed to cover any metrology operation procedure used to extract metrology information relating to one or more structural elements on a semiconductor specimen. In some embodiments, the metrology operations can include measurement operations, such as, e.g., critical dimension (CD) measurements performed with respect to certain structural elements on the specimen, including but not limited to the following: dimensions (e.g., line widths, line spacing, contact diameters, size of the element, edge roughness, gray level statistics, etc.), shapes of elements, distances within or between elements, related angles, overlay information associated with elements corresponding to different design levels, etc. Measurement results such as measured images are analyzed, for example, by employing image-processing techniques. Note that, unless specifically stated otherwise, the term “metrology”, or derivatives thereof used in this specification, is not limited with respect to measurement technology, measurement resolution, or size of inspection area.

The term “defect” used in this specification should be expansively construed to cover any kind of abnormality or undesirable feature/functionality formed on a specimen. In some cases, a defect may be a defect of interest (DOI) which is a real defect that has certain effects on the functionality of the fabricated device, thus is in the customer's interest to be detected. For instance, any “killer” defects that may cause yield loss can be indicated as a DOI. In some other cases, a defect may be a nuisance (also referred to as “false alarm” defect) which can be disregarded because it has no effect on the functionality of the completed device and does not impact yield.

The term “defect candidate” used in this specification should be expansively construed to cover a suspected defect location on the specimen which is detected to have a relatively high probability of being a defect of interest (DOI). Therefore, a DOI candidate, upon being reviewed/tested, may actually be a DOI, or, in some other cases, it may be nuisances, or random noise that can be caused by different variations (e.g., process variation, color variation, mechanical and electrical variations, etc.) during inspection.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats as, by way of non-limiting examples, GDSII format, OASIS format, etc. Design data can be presented in vector format, grayscale intensity image format, or otherwise.

The term “image(s)” or “image data” used in the specification should be expansively construed to cover any original images/frames of the specimen captured by an examination tool during the fabrication process, derivatives of the captured images/frames obtained by various pre-processing stages, and/or computer-generated synthetic images (in some cases based on design data). Depending on the specific way of scanning (e.g., one-dimensional scan such as line scanning, two-dimensional scan in both x and y directions, or dot scanning at specific spots, etc.), image data can be represented in different formats, such as, e.g., as a gray level profile, a two-dimensional image, or discrete pixels, etc. It is to be noted that in some cases the image data referred to herein can include, in addition to images (e.g., captured images, processed images, etc.), numeric data associated with the images (e.g., metadata, hand-crafted attributes, etc.). It is further noted that images or image data can include data related to a processing step/layer of interest, or a plurality of processing steps/layers of a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the present detailed description, numerous specific details are set forth in order to provide a thorough understanding of the methods and apparatus.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A computerized system of algorithm performance prediction, the system comprising a processing circuitry configured to:
obtain one or more sets of images acquired from one or more sites of a semiconductor specimen to be examined by a target algorithm;
extract values of a set of image attributes from the one or more sets of images, wherein the set of image attributes is expected to result in varied responses from the target algorithm; and
provide the values of the set of image attributes to a variation model to predict performance of the target algorithm with respect to a performance metric without executing the target algorithm on the sets of images, wherein the variation model is constructed to predict how the target algorithm responds to variations in values of the set of image attributes.

2. The computerized system according to claim 1, wherein the set of image attributes comprises a subset of value attributes and a subset of statistical attributes derived from the one or more sets of images.

3. The computerized system according to claim 1, wherein the target algorithm is a metrology algorithm and the performance metric is precision, indicative of repeatability of metrology measurements obtained from the semiconductor specimen.

4. The computerized system according to claim 2, wherein the variation model is constructed to predict a relationship between output variations of the target algorithm and the subset of statistical attributes, the relationship being parameterized by a position within a multi-dimensional attribute space defined by values of the subset of value attributes.

5. The computerized system according to claim 1, wherein the target algorithm is an overlay algorithm usable for obtaining an overlay measurement between a first layer and a second layer in the semiconductor specimen, wherein each set of images acquired from a respective site comprises at least one image for each layer, and the set of image attributes comprises a pair of gray level (GL) profiles corresponding to a pair of regions of interest (ROIs) defined on each layer, and noise statistics extracted from the pair of ROIs.

6. The computerized system according to claim 5, wherein the overlay algorithm is configured based on a correlation graph between the pair of GL profiles for each layer, and the variation model is configured to predict a probability of correlation noises surpassing a correlation maximum indicated by the correlation graph.

7. The computerized system according to claim 6, wherein the probability is calculated based on the correlation noise and a gap between a correlation value at each position of the correlation graph and the correlation maximum.

8. The computerized system according to claim 5, wherein the predicted performance is with respect to precision of the overlay measurement, which is determined based on predictions derived independently from a secondary electron (SE) image and a backscattered electron (BSE) image.

9. The computerized system according to claim 6, wherein the variation model is further configured to estimate a statistical error representing variations in overlay measurements based on probabilities calculated across a range of delta distances from the correlation maximum.

10. The computerized system according to claim 1, wherein the target algorithm is a critical dimension (CD) algorithm usable for providing a CD measurement for a given feature of the semiconductor specimen, and the performance metric is precision.

11. The computerized system according to claim 1, wherein the target algorithm is a defect examination algorithm usable for examining the semiconductor specimen, and the performance metric is detection accuracy of defects detected in the semiconductor specimen.

12. A computerized method of algorithm performance prediction, the method comprising:
obtaining one or more sets of images acquired from one or more sites of a semiconductor specimen to be examined by a target algorithm;
extracting values of a set of image attributes from the one or more sets of images, wherein the set of image attributes is expected to result in varied responses from the target algorithm; and
providing the values of the set of image attributes to a variation model to predict performance of the target algorithm with respect to a performance metric without executing the target algorithm on the sets of images, wherein the variation model is constructed to predict how the target algorithm responds to variations in values of the set of image attributes.

13. The computerized method according to claim 12, wherein the set of image attributes comprises a subset of value attributes and a subset of statistical attributes derived from the one or more sets of images.

14. The computerized method according to claim 13, wherein the variation model is constructed to predict a relationship between output variations of the target algorithm and the subset of statistical attributes, the relationship being parameterized by a position within a multi-dimensional attribute space defined by values of the subset of value attributes.

15. The computerized method according to claim 12, wherein the target algorithm is an overlay algorithm usable for obtaining an overlay measurement between a first layer and a second layer in the semiconductor specimen, wherein each set of images acquired from a respective site comprises at least one image for each layer, and the set of image attributes comprises a pair of gray level (GL) profiles corresponding to a pair of regions of interest (ROIs) defined on each layer, and noise statistics extracted from the pair of ROIs.

16. The computerized method according to claim 15, wherein the overlay algorithm is configured based on a correlation graph between the pair of GL profiles for each layer, and the variation model is configured to predict a probability of correlation noises surpassing a correlation maximum indicated by the correlation graph.

17. The computerized method according to claim 16, wherein the probability is calculated based on the correlation noise and a gap between a correlation value at each position of the correlation graph and the correlation maximum.

18. The computerized method according to claim 16, wherein the variation model is further configured to estimate a statistical error representing variations in overlay measurements based on probabilities calculated across a range of delta distances from the correlation maximum.

19. The computerized method according to claim 12, wherein the target algorithm is a defect examination algorithm usable for examining the semiconductor specimen, and the performance metric is detection accuracy of defects detected in the semiconductor specimen.

20. A non-transitory computer readable storage medium tangibly embodying a program of instructions that, when executed by a computer, cause the computer to perform a method of algorithm performance prediction, the method comprising:
obtaining one or more sets of images acquired from one or more sites of a semiconductor specimen to be examined by a target algorithm;
extracting values of a set of image attributes from the one or more sets of images, wherein the set of image attributes is expected to result in varied responses from the target algorithm; and
providing the values of the set of image attributes to a variation model to predict performance of the target algorithm with respect to a performance metric without executing the target algorithm on the sets of images, wherein the variation model is constructed to predict how the target algorithm responds to variations in values of the set of image attributes.
